(19) United States
(12) Patent Application Publication
(10) Pub. No.: US 2024/0387345 A1
(43) Pub. Date: Nov. 21, 2024

(54) CIRCUIT BOARD DEVICE WITH INDUCTOR(S) FOR ROUTING POWER FROM A POWER MANAGEMENT INTEGRATED CIRCUIT (IC) (PMIC) TO A SECONDARY CIRCUIT BOARD, AND RELATED ASSEMBLY METHODS

(71) Applicant: QUALCOMM Incorporated, San Diego, CA (US)

(72) Inventors: Venkatesh Sadineni, Hyderabad (IN); Prachir Puri, Hyderabad (IN); Veera Venkata Charan Junnu, Peddapuram (IN); Chintalapudi Manikanta Varaprasada Lakshmi, Visakhapatnam (IN)

(21) Appl. No.: 18/319,852

(22) Filed: May 18, 2023

(51) Int. Cl. H01L 23/498; H01L 21/48; H01L 23/00; H01L 23/552; H01L 23/66; H01L 25/16; H05K 1/14

(52) U.S. Cl. CPC H01L 23/49838; H01L 21/4846; H01L 23/552; H01L 23/66; H01L 24/16; H01L 24/17; H01L 25/162; H05K 1/145; H01L 2224/16225; H01L 2224/17515; H01L 2924/1421; H01L 2924/1427; H05K 2201/10015; H05K 2201/1003

(57) ABSTRACT

A circuit board device employing stacked circuit boards with an inductor(s) for routing power from a power management integrated circuit (IC) (PMIC) to a secondary circuit board, and related fabrication methods. The inductor(s) is coupled between the first circuit board and the second circuit board in a first, vertical direction as part of a power routing path between the PMIC on the first circuit board and a second electronic component(s) of the second circuit board. In this manner, the PMIC can be shared between the first and second circuit boards to manage power signals supplied to both the first electronic component(s) of the first circuit board and second electronic component(s) of the second circuit board. The inductor(s) can also be strategically located to provide a shorter power signal routing path with reduced impedance between the PMIC and the second electronic component(s) to reduce or avoid power performance issues.

### BACKGROUND

### I. Field of the Disclosure

The field of the disclosure relates to electronic devices that include a printed circuit board (PCB) with mounted electrical components and integrated circuit (IC) chip(s), and more particularly to electronic devices that include stacked PCBs.

### II. Background

Electronic devices, such as smartphones, laptops, and televisions, have revolutionized modern society by enabling communication, entertainment, and access to information on a global scale. These electronic devices include circuit boards, also known as “printed circuit boards” (PCBs). A PCB is an electronic assembly that includes one or more conductive layers that include metal lines or traces to provide electrical connections and electrical signal paths between electronic components coupled to the PCB. Electrical components, such as integrated circuit (IC) chips and passive electrical components (e.g., resistors, capacitors, inductors), are physically mounted to a PCB to provide electrical circuity connectivity for the electronic components. The PCB electrical components are also electrically coupled to external metal interconnects (e.g., metal pads) on the PCB that are then electrically coupled to signal routing paths provided in the conductive layers of the PCB to provide electrical connections and electrical signal paths between electronic components coupled to the PCB.

Demand for smaller and more powerful electronic devices has led to the development of multi-layer PCBs. Multi-layer PCBs can be combined or “stacked” together to form a stacked PCB. A stacked PCB includes multiple PCBs that each have their own conductive layers and electrical components coupled to the PCB. The multiple PCBs are stacked on top of each other vertically with electrical signal paths provided in their respective conductive layers electrically interconnected to each other. For example, a first PCB in the stacked PCB device could include an application processor(s) and first power management integrated circuit (PMIC) to manage power supplied to the application processor(s). A second PCB in the stacked PCB device could include a radio-frequency (RF) transceiver and a second PMIC to manage power supplied to the RF transceiver. In this manner, the RF transceiver and application processor(s) are physically separated from each other with their signal routing provided in the respective PCBs to minimum signal interference. However, electronic components in the stacked PCBs can be electrically connected to each other through standoff conductive structures, such as metal posts or vias, between the stacked PCBs. Providing an electronic device with stacked PCBs may also provide more flexibility in different manufacturers or suppliers being able to provide each PCB as a standalone device, that is tested separately, and then assembled in a stacked PCB arrangement as part of a separate assembly process.

### SUMMARY OF THE DISCLOSURE

Aspects disclosed herein include a circuit board device with an inductor(s) for routing power from a power management integrated circuit (IC) (PMIC) to a secondary circuit board. Related assembly methods are also disclosed. The circuit board device includes a first electronic device that includes a first circuit board (e.g., a first printed circuit board (PCB)), a first electronic component(s) (e.g., an application processor) coupled to the first circuit board, and a PMIC coupled to the first circuit board. The PMIC manages power supplied to the first electronic component(s). The circuit board device also includes a second electronic device that includes a second circuit board (e.g., a second PCB) and a second electronic component(s) (e.g., a radio-frequency (RF) transceiver) coupled to the second circuit board. The first and second circuit boards are stacked on top of each other in a first, vertical direction and coupled to each other through standoff conductive structures (e.g., solder joints, metal posts, vias, edge connectors) to provide both physical standoff connections and signal routing paths between the first electronic component(s) and the second electronic component(s). In exemplary aspects, the PMIC of the first circuit board is shared with the second circuit board such that the PMIC of the first circuit board also manages power supplied to the second electronic component(s) of the second circuit board. In this manner, the PMIC can be shared between the first and second circuit boards to manage power signals supplied to both the first and second electronic component(s) to reduce costs and conserve area in the stacked circuit boards. Separate PMICs are not required for each of the first and second circuit boards to manage power for only their respective first and second electronic components.

In other exemplary aspects, to provide a power routing path between the PMIC on the first circuit board and the second circuit board, the circuit board device includes an inductor(s) that is coupled between the first circuit board and the second circuit board in the first, vertical direction. The inductor can act as an interposer connection between the first circuit board and the second circuit board. The inductor(s) forms part of a power routing path between the PMIC and the second electronic component(s) of the second circuit board. The inductor(s) is coupled to a power port of the PMIC of the first circuit board, through its coupling to the first circuit board. The inductor(s) is also coupled to the second electronic component(s) of the second circuit board, through its coupling to the second circuit board. By providing the inductor(s) as part of the power routing path between the first and second circuit boards, the inductor(s) can be more strategically located to reduce the length of the power routing path between the PMIC and the second electronic component(s). In this manner, the power routing path between the PMIC and the second electronic component(s) will have a reduced impedance to avoid power performance issues, such as undesired voltage drop, power signal losses, and electro-magnetic interference (EMI) issues. This is opposed to having to provide the power routing path through other conductive structures (e.g., the standoff conductive structures) that may be located farther away from the PMIC (e.g., at the periphery of the circuit boards).

In another exemplary aspect, the power routing path between the first and second circuit board in the circuit board device also includes one or more ground signal routing paths to provide a ground return path from the second electronic component(s) of the second circuit board back to the PMIC of the first circuit board. In one exemplary aspect, the ground signal routing path includes a separate shorting conductor that is coupled in the first, vertical direction between the first and second circuit boards and coupled to ground of the PMIC and the second electronic component(s). The shorting conductor can also provide power switching noise isolation between the inductor and other first and/or second electronic components to provide for faster transient responses in the PMIC.

In another exemplary aspect, to further reduce the inductance loop of the inductor (e.g., avoid or mitigate undesired EMI, signal interference, and/or power switching noise isolation issues), the inductor can be provided as a ground-shielded inductor. The ground-shielded inductor is a structure that includes an inductor core surrounded by an integrated conductive core with a dielectric material disposed between the inductor core and conductive core to prevent shorting of the inductor core to the conductive core. The conductive core can be coupled to ground and magnetically couple the inductance loop of the inductor to ground to reduce the inductance loop of the inductor. By the conductive core being integrated in the ground-shielded inductor, the conductive core is more able to magnetically couple the inductance loop of the inductor to ground to reduce the inductance loop. Thus, the conductive core acts as a ground shield to the inductor to mitigate the inductor from acting as an antenna and thus reduce EMI with signals carried over signal routing paths in the first and second circuit boards. The shorting conductor can also provide power switching noise isolation between the inductor and other electrical components to provide for faster transient responses in the PMIC.

In another example, the dielectric material of the ground-shielded inductor is selected to have a lower dielectric constant (e.g., carbon-doped oxide, highly porous oxide). This minimizes the capacitance between the conductive core and the inductor, and thus reduces added capacitance between the inductor and ground. The inductor can also include multiple terminals that include first terminals connected the inductor core to place the inductor core in the power signal routing path, and separate, second terminals connected to the integrated conductive core to place the integrated conductive core in the power ground routing path.

In this regard, in one exemplary aspect, a circuit board device is provided. The circuit board device comprises a first electronic device. The first electronic device comprises a first circuit board. The first electronic device also comprises a PMIC comprising a first power port coupled to the first circuit board and a second power port coupled to the first circuit board. The first electronic device also comprises a first electronic component coupled to the first power port through the first circuit board. The circuit board device also comprises a second electronic device comprising a second circuit board coupled to the first circuit board in a first direction, and a second electronic component coupled to the second circuit board. The circuit board device also comprises an inductor coupled to the first circuit board and the second circuit board in the first direction. The inductor is coupled to the second electronic component through the second circuit board. The inductor is also coupled to the second power port through the first circuit board.

In another exemplary aspect, a method of assembling a circuit board device is provided. The method comprises providing a first electronic device, comprising providing a first circuit board coupling a first power port and a second power port of a power management integrated circuit (PMIC) to the first circuit board, and coupling a first electronic component to the first power port. The method also comprises providing a second electronic device, comprising providing a second circuit board, and coupling a second electronic component to the second circuit board. The method also comprises coupling an inductor to the first circuit board in a first direction to couple the inductor to the second power port. The method also comprises coupling the inductor to the second circuit board to couple the inductor to the second electronic component.

### BRIEF DESCRIPTION OF THE FIGURES

FIG. 1A is a side view of a circuit board device that includes a first circuit board stacked on a second circuit board, and wherein the circuit board device further includes an inductor(s) and separate shorting conductor coupled between the first circuit board and the second circuit board as part of a power routing path between the first circuit board and the second circuit board, for a power management integrated circuit (IC) (PMIC) on the first circuit board to be shared between the first and second circuit boards to manage the supply of power to the first circuit board and to a second electronic component(s) of the second circuit board;

FIG. 1B is a close-up side view of a portion of the circuit board device in FIG. 1A;

FIG. 2 is a side view of a circuit board device that includes a first circuit board stacked on a second circuit board, and wherein a separate PMIC is provided on each circuit board to manage the supply of power to an electronic component(s) on its respective circuit board;

FIG. 3 is a side view of another circuit board device that includes a first circuit board stacked on a second circuit board, and wherein a second electronic component(s) of the second circuit board receives power through a power routing path provided through standoff conductive structures coupled to the PMIC on the first circuit board;

FIG. 4 is a side view of another circuit board device that includes a first circuit board stacked on a second circuit board, and wherein the circuit board device further includes a ground-shielded inductor(s) that includes an inductor core surrounded by an integrated conductive core that are both coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board;

FIGS. 5A-5D are side perspective, front perspective, cross-sectional front, and top views, respectively, of an exemplary box-shaped ground-shielded inductor that can be included as an inductor in FIG. 4;

FIGS. 6A-6C are front perspective, cross-sectional front, and top views, respectively, of another exemplary cylindrical-shaped ground-shielded inductor that can be included as an inductor in FIG. 4;

FIG. 7 is a flowchart illustrating an exemplary assembly process of assembling a circuit board device that includes a first circuit board stacked on a second circuit board, and wherein the circuit board device further includes a ground-shielded inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices in FIGS. 1A-1B and 4;

FIGS. 8A-8C is a flowchart illustrating another exemplary assembly process of assembling a circuit board device that includes a first circuit board stacked on a second circuit board, and wherein the circuit board device further includes a ground-shielded inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices in FIGS. 1A-1B and 4;

FIGS. 9A-9F are exemplary assembly stages during assembly of the circuit board device according to the assembly process in FIGS. 8A-8C;

FIG. 10 is a block diagram of an exemplary processor-based system that can be provided as or included in a circuit board device(s) that includes a first circuit board stacked on a second circuit board, and wherein the circuit board device(s) further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices in FIGS. 1A-1B and 4, and that can be assembled according to the assembly processes in FIGS. 7-8C; and

FIG. 11 is a block diagram of an exemplary wireless communications device that includes radio-frequency (RF) components that can be provided as or included in a circuit board device(s) that includes a first circuit board stacked on a second circuit board device, and wherein the circuit board device(s) further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices in FIGS. 1A-1B and 4, and that can be assembled according to the assembly processes in FIGS. 7-8C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a circuit board device with an inductor(s) for routing power from a power management integrated circuit (IC) (PMIC) to a secondary circuit board. Related assembly methods are also disclosed. The circuit board device includes a first electronic device that includes first circuit board (e.g., a first printed circuit board (PCB), a first electronic component(s) (e.g., an application processor) coupled to the first circuit board, and a PMIC coupled to the first circuit board. The PMIC manages power supplied to the first electronic component(s). The circuit board device also includes a second electronic device that includes a second circuit board (e.g., a second PCB) and a second electronic component(s) (e.g., a radio-frequency (RF) transceiver) coupled to the second circuit board. The first and second circuit boards are stacked on top of each other in a first, vertical direction and coupled to each other through standoff conductive structures (e.g., solder joints, metal posts, vias, edge connectors) to provide both physical standoff connections and signal routing paths between the first electronic component(s) and second electronic component(s). In exemplary aspects, the PMIC of the first circuit board is shared with the second circuit board such that the PMIC of the first circuit board also manages power supplied to the second electronic component(s) of the second circuit board. In this manner, the PMIC can be shared between the first and second circuit boards to manage power signals supplied to both the first and second electronic component(s) to reduce costs and conserve area in the stacked circuit boards. Separate PMICs are not required for each of the first and second circuit boards to manage power for only their respective first and second electronic components.

In other exemplary aspects, to provide a power routing path between the PMIC on the first circuit board and the second circuit board, the circuit board device includes an inductor(s) that is coupled between the first circuit board and the second circuit board in the first, vertical direction. The inductor can act as an interposer connection between the first circuit board and the second circuit board. The inductor(s) forms part of a power routing path between the PMIC and the second electronic component(s) of the second circuit board. The inductor(s) is coupled to a power port of the PMIC of the first circuit board, through its coupling to the first circuit board. The inductor(s) is coupled is also coupled to the second electronic component(s) of the second circuit board, through its coupling to the second circuit board. By providing the inductor(s) as part of the power routing path between the first and second circuit boards, the inductor(s) can be more strategically located to reduce the length of the power routing path between the PMIC and the second electronic component(s). In this manner, the power routing path between the PMIC and the second electronic component(s) will have a reduced impedance to avoid power performance issues, such as undesired voltage drop, power signal losses, electro-magnetic interference (EMI) issues. This is opposed to having to provide the power routing path through other conductive structures (e.g., the standoff conductive structures) that may be located farther away from the PMIC (e.g., at the periphery of the circuit boards).

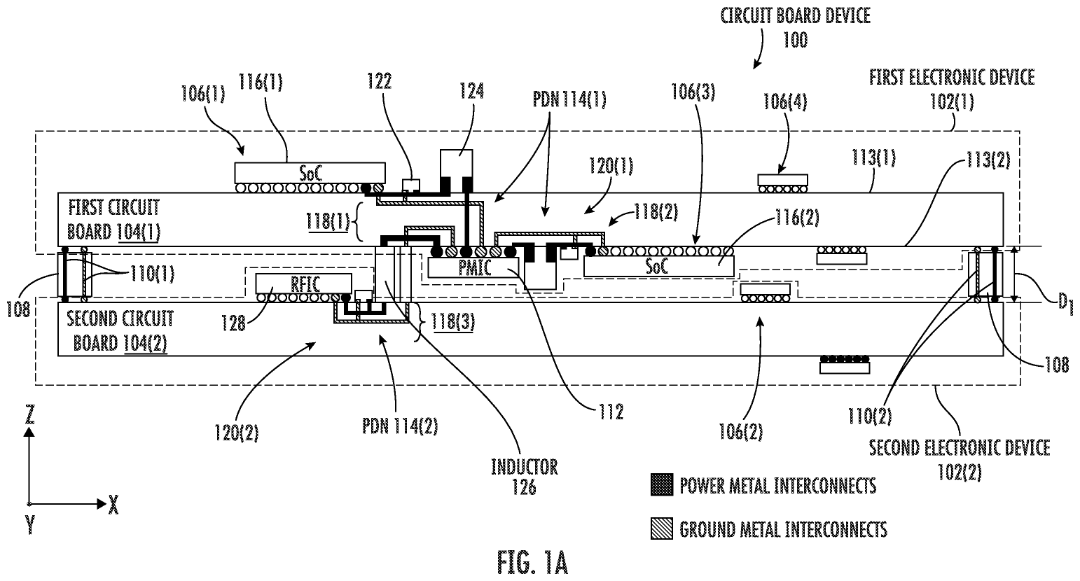

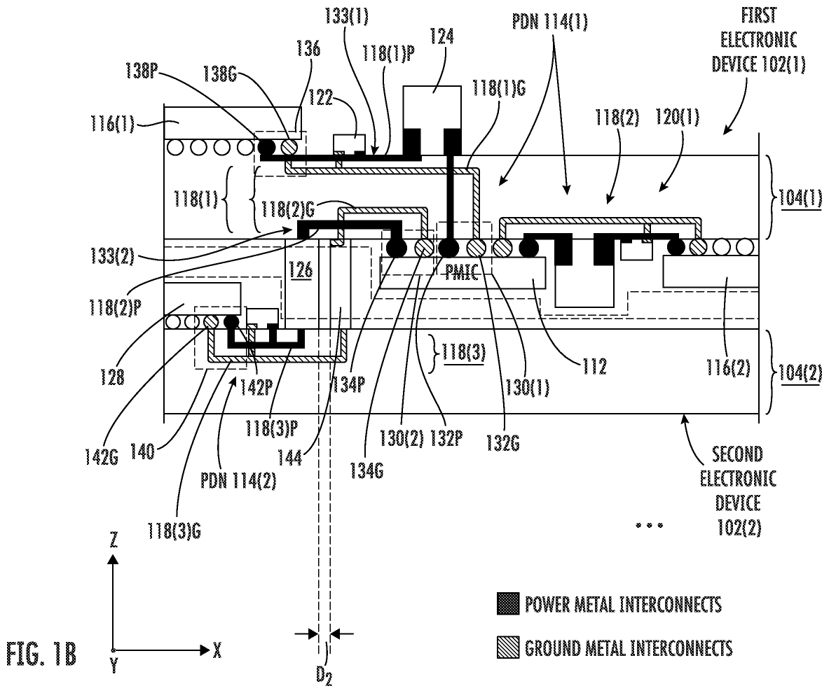

In this regard, FIG. 1A is a side view of a circuit board device 100 (also referred to herein as “stacked circuit board device 100”) that includes a first electronic device 102(1) and a second electronic device 102(2) stacked on top of each other in a first, vertical direction (Z-axis direction). The first electronic device 102(1) includes a first circuit board 104(1) (e.g., a printed circuit board (PCB)) that includes first electronic components 106(1) coupled to the first circuit board 104(1). The second electronic device 102(2) includes a second circuit board 104(2) (e.g., a PCB) that includes second electronic components 106(2) coupled to the second circuit board 104(2). The stacked circuit board device 100 includes one or more standoff conductive structures 108 (e.g., solder joints, metal posts, vias, edge connectors) that is connected to the first circuit board 104(1) and the second circuit board 104(2) to provide a physical support for stacking and connecting the first circuit board 104(1) and the second circuit board 104(2) together in the first, vertical direction (Z-axis direction). The standoff conductive structure 108 provides for a gap distance D1 between the first and second circuit boards 104(1), 104(2) in the first, vertical direction (Z-axis direction). The first and second circuit boards 104(1), 104(2) are at least partially parallel to each other in a second, horizontal direction (X- and Y-axes directions) orthogonal to the first, vertical direction (Z-axis direction). For example, the standoff conductive structure 108 can be an interposer frame. The standoff conductive structure 108 in this example also includes one or more vertical conductors 110(1), 110(2) (e.g., metal posts, metal vias) that provide conductive signal paths between the first circuit board 104(1) and the second circuit board 104(2) so that a first electronic component 106(1) in the first circuit board 104(1) of the first electronic device 102(1) can be electrically coupled to a second electronic component(s) 106(2) in the second circuit board 104(2) of the second electronic device 102(2), as part of the stacked circuit board device 100.

With continuing reference to FIG. 1A, the first electronic device 102(1) includes a PMIC 112 as one of the first electronic components 106(1) that is coupled to the first circuit board 104(1). In this example, the PMIC 112 is coupled to a second surface 113(2) of the first circuit board 104(1) that is opposite of a first surface 113(1) of the first circuit board 104(1) in the first, vertical direction (Z-axis direction). Thus, the PMIC 112 on the second surface 113(2) is between the first and second circuit boards 104(1), 104(2) and adjacent to the second circuit board 104(2) in the first, vertical direction (Z-axis direction). The PMIC 112 is configured to manage the supply of power in a first power distribution network (PDN) 114(1) in the first circuit board 104(1). The PMIC 112 manages the supply of power in the PDN 114(1) to the other first electronic components 106(3), 106(4) coupled to the first circuit board 104(1) as part of the first electronic device 102(1). For example, the PMIC 112 may be a switched mode power supply (SMPS). A first electronic component 106(1) that is coupled to the first circuit board 104(1) and receives power managed by the PMIC 112 as part of the first PDN 114(1) for operation in this example is a first application processor 116(1), which may be a system-on-a-chip (SoC). The first circuit board 104(1) includes first metal interconnects 118(1) (e.g., metal traces or metal lines) in one or more first metallization layers 120(1) that are part of the first PDN 114(1) to provide power routing paths between the first application processor 116(1) and the PMIC 112.

Another first electronic component 106(3) that is coupled to the first circuit board 104(1) and receives power managed by the PMIC 112 as part of the first PDN 114(1) in this example is a second application processor 116(2), which may also be a SoC. The first circuit board 104(1) includes second metal interconnects 118(2) (e.g., metal traces or metal lines) in the one or more first metallization layers 120(1) that are also part of the first PDN 114(1) to provide power routing paths between the second application processor 116(2) and the PMIC 112 for providing power to the second application processor 116(2) for operation. The first electronic device 102(1) in this example also includes a surface mounted decoupling capacitor 122 as another first electronic component 106(1) that is coupled to the first circuit board 104(1) and is configured to provide a decoupling capacitance as part of the first PDN 114(1). The first electronic device 102(1) in this example also includes a surface mounted inductor 124 as another first electronic component 106(1) that is also coupled to the first circuit board 104(1) and is configured to provide an inductance in the first PDN 114(1) to store energy, such as during off switching times of the power supply in the PMIC 112.

As discussed in more detail below, to allow for the PMIC 112 in the first electronic device 102(1) coupled to the first circuit board 104(1) to be shared and also manage the supply of power to the second electronic components 106(2) in the second electronic device 102(2), the stacked circuit board device 100 includes an inductor 126. In this example, the inductor 126 is disposed between and coupled to the first circuit board 104(1) and the second circuit board 104(2) in the first, vertical direction (Z-axis direction). In this example, the inductor 126 acts as an interposer connection between the first circuit board 104(1) and the second circuit board 104(2). For example, the inductor 126 may be connected (e.g., soldered) between the first and/or second metal interconnects 118(1), 118(2) in the first PDN 114(1) in the first circuit board 104(1), and third metal interconnects 118(3) in a second PDN 114(2) in the second circuit board 104(2) to electrically couple (e.g., directly connects) the first and second PDNs 114(1), 114(2) together. The inductor 126 couples (e.g., directly connects) the first PDN 114(1) in the first circuit board 104(1) in series to the second PDN 114(2) in the second circuit board 104(2) to distribute power from the shared PMIC 112 to one or more second electronic components 106(2) in the second electronic device 102(2).

In this regard, the second circuit board 104(2) includes the third metal interconnects 118(3) (e.g., metal traces or metal lines) in one or more second metallization layers 120(2) that are also part of the second PDN 114(2) to provide power routing paths between the inductor 126 and the first PDN 114(1) and the PMIC 112 in the first circuit board 104(1). The inductor 126 is coupled to a RFIC 128 as a second electronic component 106(2) in the second circuit board 104(2) in this example. Thus, as discussed in more detail below, power signals can flow from the PMIC 112 and the first PDN 114(1) in the first circuit board 104(1), through the inductor 126 and to the second PDN 114(2) and RFIC 128 in the second circuit board 104(2) to provide power to the RFIC 128 for operation. The inductor 126 not only provides an inductance in the second PDN 114(2), but it also provides a power routing path between the first PDN 114(1) in the first circuit board 104(1) and the second PDN 114(2) in the second circuit board 104(2). In this manner, the PMIC 112 can be shared between the first and second PDNs 114(1), 114(2) in the first and second circuit boards 104(1), 104(2) to manage power supplied to both the first and second electronic component(s) 106(1), 106(2) in both the respective first and second circuit boards 104(1), 104(2) to reduce costs and conserve area in the stacked circuit board device 100. Thus, by sharing the PMIC 112 between the first and second PDNs 114(1). 114(2) in the first and second circuit boards 104(1), 104(2), an additional separate PMIC(s) is not required to manage the supply of power to the second electronic components(s) 106(2) in the second electronic device 102(2) in this example.

Also, by providing the inductor 126 as part of the power routing path between the first and second PDNs 114(1), 114(2) of the respective first and second circuit boards 104(1), 104(2), the inductor 126 can be more strategically located on the first circuit board 104(1) to reduce the length of the power routing path between the PMIC 112 and the second electronic component(s) 106(2) in the second circuit board 104(2). In this manner, the power routing path between the PMIC 112 and the second electronic component(s) 106(2) will have a reduced impedance to avoid power performance issues, such as undesired voltage drop, power signal losses, and electro-magnetic interference (EMI) issues. This is opposed to having to provide the power routing path through other conductive structures, such as the standoff conductive structures 108, that may be located farther away from the PMIC 112, such as at the periphery of the first and second circuit boards 104(1), 104(2) as shown in FIG. 1A.

To discuss additional exemplary detail of the stacked circuit board device 100 in FIG. 1A and the coupling of the first and second circuit boards 104(1), 104(2) through the inductor 126 to couple their first and second PDNs 114(1), 114(2) together to supply power from the PMIC 112 to the second electronic device 102(2), FIG. 1B is provided. FIG. 1B is a close-up side view of a portion of the stacked circuit board device 100 in FIG. 1A to discuss more exemplary detail below.

As shown in FIG. 1B, the PMIC 112 includes a first power port 130(1) and a second power port 130(2) coupled (e.g., directly connected) to the first circuit board 104(1). The first power port 130(1) includes a first power signal port 132P and a first ground signal port 132G. In this example, the first power signal port 132P and the first ground signal port 132G are provided through external metal interconnects (e.g., bumps) of the PMIC 112 coupled to the first circuit board 104(1). The first power signal port 132P is configured to carry a first power signal 133(1) from the PMIC 112 as part of the first PDN 114(1). The first ground signal port 132G is configured to be coupled to ground of the PMIC 112 as part of the first PDN 114(1) to provide a return signal path from an electronic component powered through the first power port 130(1). The second power port 130(2) includes a second power signal port 134P and a second ground signal port 134G, which in this example are provided through external metal interconnects (e.g., bumps) of the PMIC 112 also coupled to the first circuit board 104(1). The second power signal port 134P is configured to carry a second power signal 133(2) from the PMIC 112 as part of the first PDN 114(1). The second ground signal port 132G is configured to be coupled to ground of the PMIC 112 as part of the first PDN 114(1) to provide a return signal path from an electronic component powered through the second power port 130(2).

With continuing reference to FIG. 1B, power and ground metal interconnects 118(1)P. 118(1)G of the first circuit board 104(1) are coupled to the first power signal port 132P and the first ground signal port 132G of the first power port 130(1) to couple the first electronic component 106(1) of the first application processor 116(1) to the first PDN 114(1) to receive power from the PMIC 112 for operation. In this regard, the first application processor 116(1) includes a first input power port 136 that includes a first input power signal port 138P and a first input ground signal port 138G. In this example, the first input power signal port 138P and the first input ground signal port 138G are provided through external metal interconnects (e.g., bumps) of the PMIC 112 coupled to the first circuit board 104(1). In this example, the first input power signal port 138P of the first application processor 116(1) is coupled in series to the inductor 124, which is coupled to the first power signal port 132P of the PMIC 112. The first input ground signal port 138G of the first application processor 116(1) is coupled (e.g., directly connected) in series to the decoupling capacitor 122, which is coupled to the first ground signal port 132G of the PMIC 112.

With continuing reference to FIG. 1B, to provide power from the PMIC 112 to the second circuit board 104(2) and its second PDN 114(2), second power and ground metal interconnects 118(2)P, 118(2)G of the first circuit board 104(1) are also coupled to the second power signal port 134P and the second ground signal port 134G of the second power port 130(2) of the PMIC 112 to couple (e.g., directly connect) the first PDN 114(1) to the second PDN 114(2). This is so that the second electronic component 106(2) coupled to the second circuit board 104(2) of the RFIC 128 receives the second power signal 133(2) from the PMIC 112 for operation. In this regard, the RFIC 128 includes a second input power port 140 that includes a second input power signal port 142P and a second input ground signal port 142G. In this example, the second input power signal port 142P and the second input ground signal port 142G are provided through external metal interconnects (e.g., bumps) of the RFIC 128 coupled to the second circuit board 104(2). In this example, the second input power signal port 142P of the RFIC 128 is coupled in series to the inductor 126, which is coupled to the second power signal port 134P of the PMIC 112. The second input ground signal port 142G of the RFIC 128 is coupled in series to a shorting conductor 144, which is coupled to the second ground signal port 134G of the PMIC 112. The shorting conductor 144 is a conductive structure, that may be, for example, a conductive metal bar, a conductive metal post, or other metal structure. The shorting conductor 144 provides a signal return path from the RFIC 128 back to the PMIC 112 from power received on the second input ground signal port 142G of the RFIC 128.

In this example, similar to the inductor 126, the shorting conductor 144 is disposed between and coupled to the first circuit board 104(1) and the second circuit board 104(2) in the first, vertical direction (Z-axis direction). In this manner, the shorting conductor 144 also provides support for the connection of the second circuit board 104(2) to the first circuit board 104(1) in the stacked circuit board device 100. For example, the shorting conductor 144 may be connected (e.g., soldered) between the second power and ground metal interconnects 118(2)P. 118(2)G in the first PDN 114(1) in the first circuit board 104(1), and third power and ground metal interconnects 118(3)P. 118(3)G in the second PDN 114(2) in the second circuit board 104(2) to electrically couple a ground signal path of the first and second PDNs 114(1), 114(2) together. The shorting conductor 144 connects the first PDN 114(1) in the first circuit board 104(1) in series to the second PDN 114(2) in the second circuit board 104(2) for a return ground signal back to the shared PMIC 112 from one or more second electronic components 106(2) in the second electronic device 102(2). In this example, the shorting conductor 144 is adjacent to the inductor 126 in the second, horizontal direction (X-axis direction). For example, the shorting conductor 144 can be adjacent to the inductor 126 by a distance D₂ in the second, horizontal direction (X-axis direction) specified by the PCB manufacturer per their design for manufacturing guidelines.

By the shorting conductor 144 being located in close proximity to the inductor 126, the shorting conductor 144 can also provide power switching noise isolation between the inductor 126 and other first and/or second electronic components 106(1), 106(2) (e.g., if the PMIC 112 has a switched power supply (SPS)) to provide for faster transient responses in the PMIC 112.

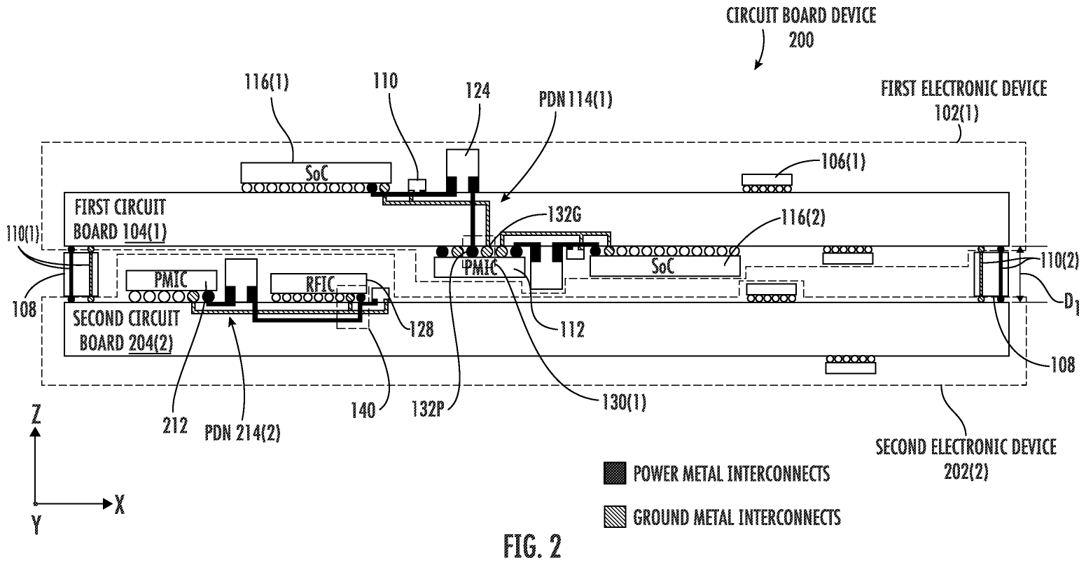

FIG. 2 is a side view of an alternative circuit board device 200 (also referred to herein as “stacked circuit board device 200”) that includes the first electronic device 102(1) that includes the first circuit board 104(1) in FIGS. 1A and 1B stacked on a second circuit board 204(2) of a second electronic device 202(2). Common elements between the stacked circuit board device 200 in FIG. 2 and the stacked circuit board device 100 in FIGS. 1A and 1B are shown with common element numbers. However, in the stacked circuit board device 200 in FIG. 2, the first PDN 114(1) provided by the PMIC 112 is not shared with the second circuit board 204(2). Instead, a second PMIC 212 is coupled to the second circuit board 204(2) that provides a second PDN 214(2) for the second circuit board 204(2) that is not coupled to the first PDN 114(1). In this regard, the RFIC 128 is powered through the second PDN 214(2) provided in the second circuit board 204(2) from the second PMIC 212. There is no inductor provided in the stacked circuit board device 200 in this example to couple the first PDN 114(1) in the first circuit board 104(1) to the second PDN 214(2) in the second circuit board 204(2), because the first and second PDNs 114(1), 214(2) are separate from each other on their respective first and second circuit boards 104(1), 204(2). Thus, the stacked circuit board device 200 will incur more cost and consume board area by having the second PMIC 212 to provide the separate second PDN 214(2) in the second circuit board 204(2).

FIG. 3 is a side view of yet another alternative circuit board device 300 (also referred to herein as “stacked circuit board device 300”) that includes the first electronic device 102(1) that includes the first circuit board 104(1) in FIGS. 1A and 1B stacked on a second circuit board 304(2) of a second electronic device 302(2). Common elements between the stacked circuit board device 300 in FIG. 3 and the stacked circuit board device 100 in FIGS. 1A and 1B are shown with common element numbers. In the stacked circuit board device 300 in FIG. 3, the first PDN 114(1) provided by the PMIC 112 is shared with the second circuit board 304(2) to also supply power to a second PDN 314(2) in the second circuit board 304(2). However, an inductor is not provided to couple the first PDN 114(1) to the second PDN 314(2). Instead, the second power port 130(2) of the PMIC 112 is coupled through the second power metal interconnect 118(2)P and the second ground metal interconnect 118(2)G coupled to the vertical conductors 110(1) of the standoff conductive structure 108 and through the third power and ground metal interconnects 318(3)P. 318(3)G to the second input power port 140 of the RFIC 128. Thus, while the PMIC 112 is shared between the first and second circuit boards 104(1), 304(2) to supply power to both the first and second PDNs 114(1), 314(2) in the respective first and second circuit boards 104(1), 304(2), the signal path length between the PMIC 112 and the RFIC 128 is much longer than in the stacked circuit board device 100 in FIGS. 1A and 1B. Thus, the second PDN 314(2) will experience more losses due to the increased impedance due to the increased signal path length between the PMIC 112 and the RFIC 128.

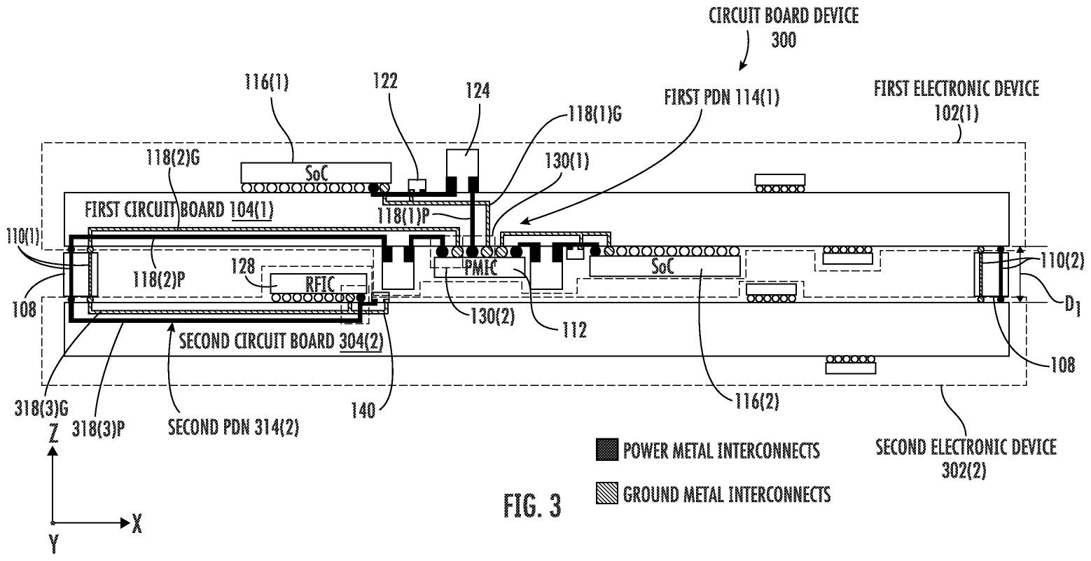

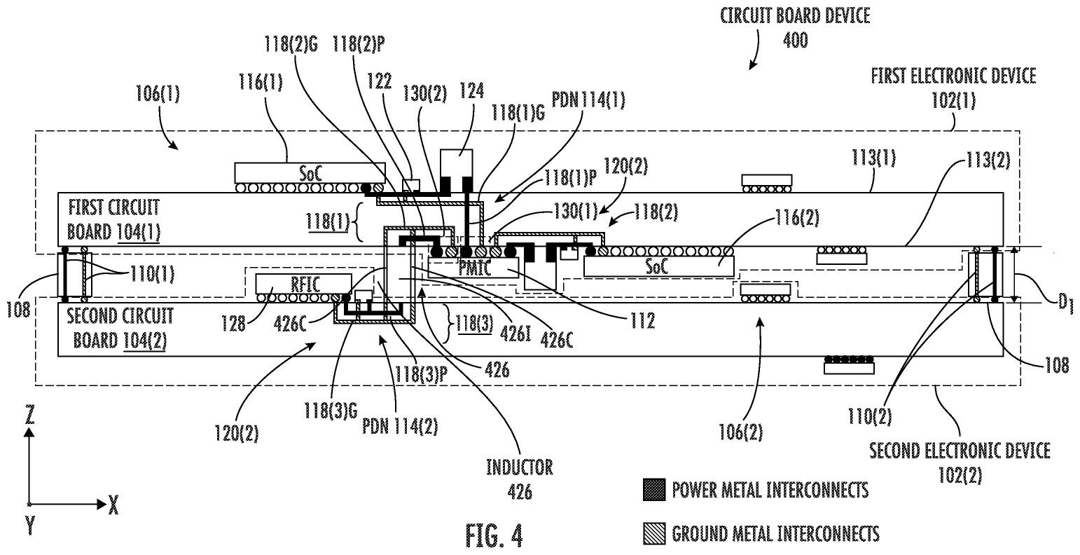

FIG. 4 is a side view of another circuit board device 400 (also referred to herein as “stacked circuit board device 400”) that includes the first electronic device 102(1) and the second electronic device 102(2) of the stacked circuit board device 100 in FIGS. 1A and 1B. Common elements between the stacked circuit board device 100 in FIGS. 1A and 1B and the stacked circuit board device 400 in FIG. 4 are shown with common element numbers. However, in the example stacked circuit board device 400 in FIG. 4, an alternative ground-shielded inductor 426 is provided to couple the first PDN 114(1) in the first circuit board 104(1) to the second PDN 114(2) in the second circuit board 104(2). In this example, the ground-shielded inductor 426 acts as an interposer connection between the first circuit board 104(1) and the second circuit board 104(2). As will be discussed in examples below, the ground-shielded inductor 426 includes a shorting conductor in the form of an inductive core 426I that provides an inductor in series to the first and second PDNs 114(1), 114(2) both coupled to the PMIC 112 in the first electronic device 102(1). The ground-shielded inductor 426 also includes a conductive core 426C that surrounds the inductive core 426I in the second, horizontal direction (X-and Y-axes directions) to provide shielding to the inductive core 426I with a dielectric material disposed between the conductive core 426C and the inductive core 426I as shown in further examples below. The conductive core 426C is shorted to ground by being coupled to and between, in series, the second ground metal interconnect 118(2)G in the first PDN 114(1) of the first circuit board 104(1) and the third ground metal interconnect 118(3)G of the second PDN 114(2) of the second circuit board 104(2) to couple the conductive core 426C to ground of the first and second PDNs 114(1), 114(2). Shorting the conductive core 426C to ground magnetically couples the inductance loop of the inductive core 426I to ground to reduce the inductance loop of the inductive core 426I. The inductive core 426I is coupled to and between, in series, the second power metal interconnect 118(2)P in the first PDN 114(1) of the first circuit board 104(1) and the third power metal interconnect 118(3)P of the second PDN 114(2) of the second circuit board 104(2) to couple the inductive core 426I to the second power port 130(2) of the PMIC 112.

In this manner, by the conductive core 426C being integrated in the ground-shielded inductor 426, the conductive core 426C is more closely located to the inductive core 426I and thus is more able to magnetically couple the inductance loop of the inductive core 426I to ground to reduce the inductance loop. The inductance loop of the inductor 426 and its inductive core 426I may be further reduced over the reduction in the inductance loop of the inductor 126 in the stacked circuit board device 100 in FIGS. 1A and 1B using the shorting conductor 144. Reducing the inductance loop of the inductive core 426I can reduce or mitigate undesired EMI, signal interference, and/or power switching noise isolation issues in the first and second PDNs 114(1), 114(2). The conductive core 426C acts as a ground shield to the inductive core 426I to mitigate the inductive core 426I from acting as an antenna and thus reduces EMI with signals carried over signal routing paths in the first and second circuit boards 104(1), 104(2). The shorting of the conductive core 426C to ground can also provide power switching noise isolation between the inductor and other electrical components to provide for faster transient responses in the PMIC.

With reference to FIG. 4, the ground-shielded inductor 426 is disposed between and coupled to the first circuit board 104(1) and the second circuit board 104(2) in the first, vertical direction (Z-axis direction). For example, the ground-shielded inductor 426 may be connected (e.g., soldered) between the first and/or second metal interconnects 118(1), 118(2) in the first PDN 114(1) in the first circuit board 104(1), and the third metal interconnects 118(3) in the second PDN 114(2) in the second circuit board 104(2) to electrically couple the first and second PDNs 114(1), 114(2) together. The ground-shielded inductor 426 couples the first PDN 114(1) in the first circuit board 104(1) in series to the second PDN 114(2) in the second circuit board 104(2) to distribute power from the shared PMIC 112 to one or more second electronic components 106(2) in the second electronic device 102(2).

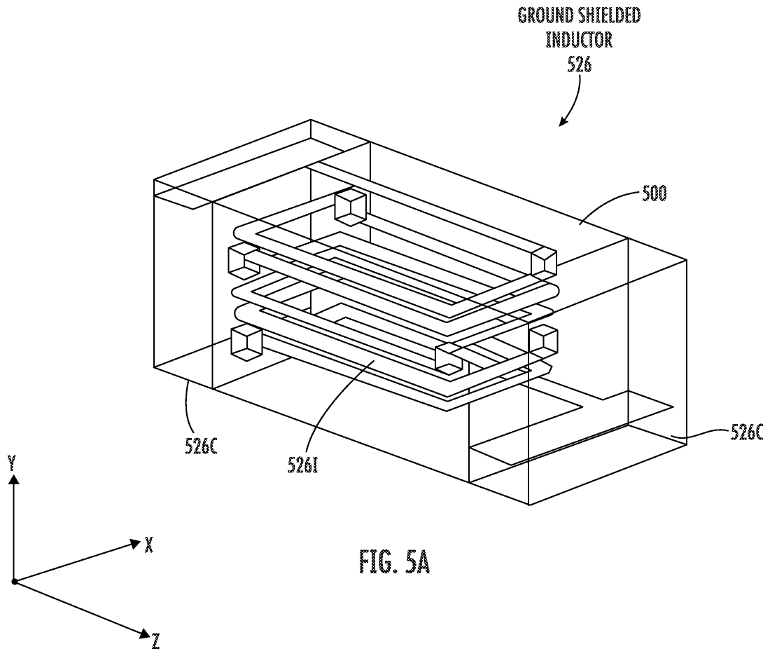

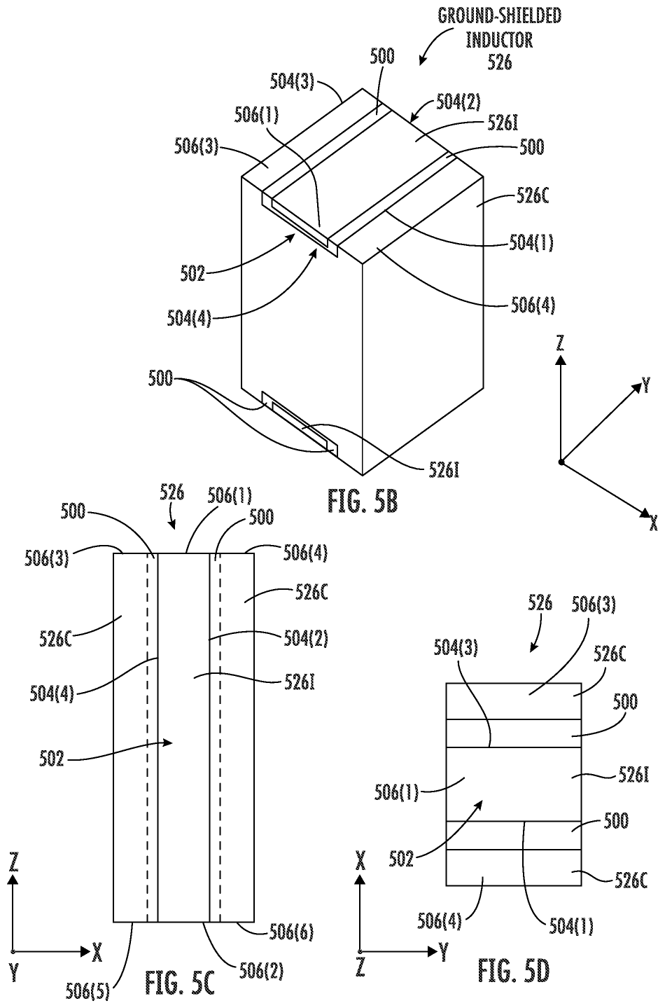

A ground-shielded inductor that can couple power distribution networks between stacked circuit boards together so that a PMIC in one circuit board can supply power to the PDN of the other stacked circuit board, like the ground-shielded inductor 426 in the circuit board device 400 in FIG. 4, can be provided in different designs. For example, FIGS. 5A-5D are side perspective, front perspective, cross-sectional front, and top views, respectively, of an exemplary box-shaped ground-shielded inductor 526 that can be included as the ground-shielded inductor 426 in FIG. 4, for example. In this regard, as shown in FIG. 5A, the ground-shielded inductor 526 includes a box-shaped inductive core 526I in the form of a metal coil. The box-shaped ground-shielded inductor 526 can provide an interposer connection between two circuit boards, such as the first and second circuit boards 104(1), 104(2) in the circuit board device 400 in FIG. 4 for example. A dielectric material 500 surrounds the box-shaped inductive core 526I to provide shorting of the box-shaped inductive core 526I from a conductive core 526C that surrounds the box-shaped inductive core 526I. As shown in FIGS. 5B-5D, the box-shaped inductive core 526I is disposed in a box-shaped cavity 502 that includes a plurality of inner surfaces 504(1)-504(4). As also shown in FIGS. 5B-5D, the box-shaped inductive core 526I is surrounded by the dielectric material 500, which is disposed on or adjacent to the inner surfaces 504(1)-504(4) and is surrounded by the conductive core 526C in the second direction (X-axis direction). The dielectric material 500 may be formed of a structure or material that has a lower dielectric constant (e.g., carbon-doped oxide, highly porous oxide) and has a dielectric constant less than or equal to 4.0. This minimizes the capacitance between the conductive core 526C and the box-shaped inductive core 526I, and thus reduces added capacitance between the ground-shielded inductor 526 and ground.

Also, as shown in FIGS. 5B-5D, the box-shaped inductive core 526I can be exposed from the ground-shielded inductor 526 such that the ends of the box-shaped inductive core 526I form first and second terminals 506(1), 506(2) to be coupled to the power metal interconnects between two circuit boards, such as the power metal interconnects 130(2)P, 130(3)P in the first and second circuit boards 104(1), 104(2) in the circuit board device 400 in FIG. 4. Also, as shown in FIGS. 5B-5D, the conductive core 526C has third and fourth terminals 506(3), 506(4) on one end and fifth and sixth terminals 506(5), 506(6) on the opposite end, each configured to be coupled to the ground metal interconnects between two circuit boards, such as the ground metal interconnects 130(2)G, 130(3)G in the first and second circuit boards 104(1), 104(2) in the circuit board device 400 in FIG. 4.

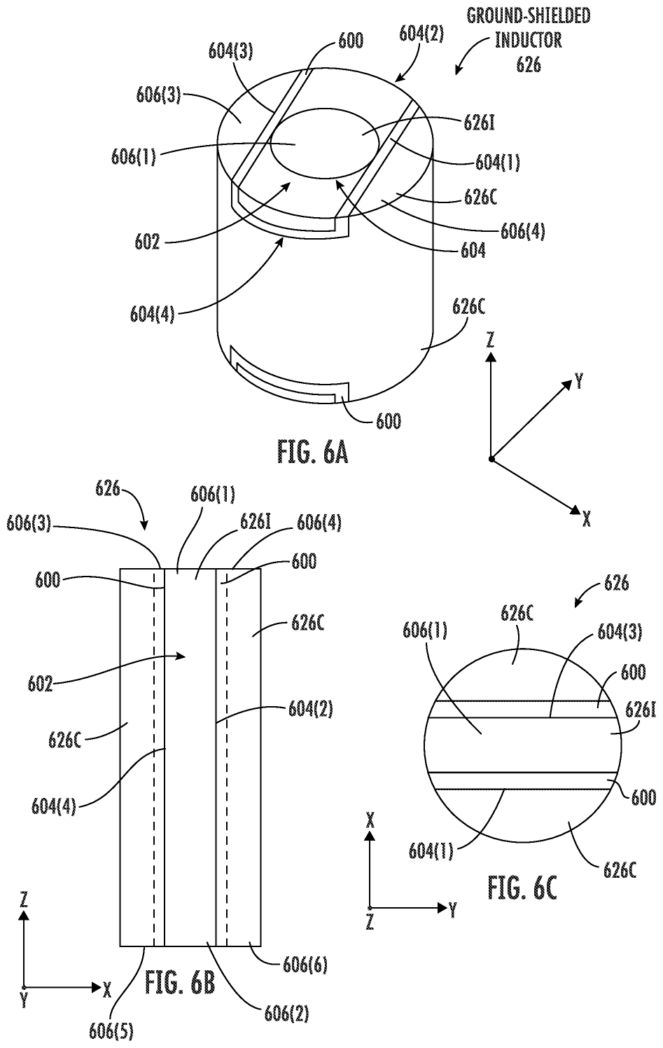

FIGS. 6A-6C are front perspective, cross-sectional front, and top views, respectively, of an exemplary cylindrical-shaped ground-shielded inductor 626 that can be included as the ground-shielded inductor 426 in FIG. 4, for example. The cylindrical-shaped ground-shielded inductor 626 can provide an interposer connection between two circuit boards, such as the first and second circuit boards 104(1), 104(2) in the circuit board device 400 in FIG. 4 for example. In this regard, as shown in FIG. 6A, the ground-shielded inductor 626 includes a cylindrical-shaped inductive core 626I in the form of a metal coil. A dielectric material 600 surrounds the cylindrical-shaped inductive core 626I to provide shorting of the cylindrical-shaped inductive core 626I from a conductive core 626C that surrounds the cylindrical-shaped inductive core 626I. As shown in FIGS. 6A-6C, the inductive core 626I is disposed in a cylindrical-shaped cavity 602 that includes a plurality of inner surfaces 604(1)-604(4). As also shown in FIGS. 6A-6C, the cylindrical-shaped inductive core 626I is surrounded by the dielectric material 600, which is disposed on or adjacent to the inner surfaces 604(1)-604(4) and is surrounded by the conductive core 626C in the second direction (X-axis direction). The dielectric material 600 may be formed of a structure or material that has a lower dielectric constant (e.g., carbon-doped oxide, highly porous oxide) and has a dielectric constant less than or equal to 4.0. This minimizes the capacitance between the conductive core 626C and the cylindrical-shaped inductive core 626I, and thus reduces added capacitance between the ground-shielded inductor 626 and ground.

Also, as shown in FIGS. 6A-6C, the cylindrical-shaped inductive core 626I can be exposed from the ground-shielded inductor 626 such that the ends of the cylindrical-shaped inductive core 626I form first and second terminals 606(1), 606(2) to be coupled to the power metal interconnects between two circuit boards, such as the power metal interconnects 118(2)P. 118(3)P in the first and second circuit boards 104(1), 104(2) in the circuit board device 400 in FIG. 4. Also, as shown in FIGS. 6A-6C, the conductive core 626C has third and fourth terminals 606(3), 606(4) on one end and fifth and sixth terminal 606(5), 606(6) on the opposite end, each configured to be coupled to the ground metal interconnects between two circuit boards, such as the ground metal interconnects 118(2)G, 118(3)G in the first and second circuit boards 104(1), 104(2) in the circuit board device 400 in FIG. 4.

An assembly process can be employed to assemble a circuit board device that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4.

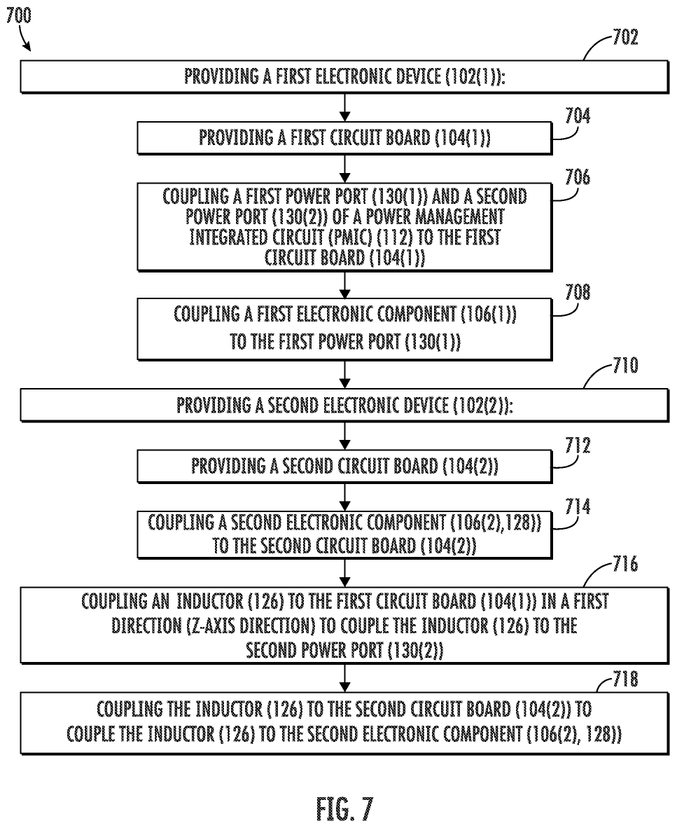

In this regard, FIG. 7 is a flowchart illustrating an exemplary assembly process 700 of assembling a circuit board device that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4. The assembly process 700 in FIG. 7 is discussed with regard to the circuit board device 100 in FIGS. 1A and 1B as an example, but note that the assembly process 700 in FIG. 7 is not limited to assembling the circuit board device 100 in FIGS. 1A-1B. The assembly process 700 in FIG. 7 could be used to fabricate other circuit board devices that include an inductor(s) coupled between the first circuit board and the second circuit board as part of a power routing path between the first circuit board and the second circuit board, for a PMIC on the first circuit board to be shared between the first and second circuit boards, including the circuit board device 400 in FIG. 4.

In this regard, as shown in FIG. 7, a first step in the assembly process 700 can be providing the first electronic device 102(1) (block 702 in FIG. 7). Providing the first electronic device 102(1) can include providing the first circuit board 104(1) (block 704 in FIG. 7), coupling the first power port 130(1) and the second power port 130(2) of the PMIC 112 to the first circuit board 104(1) (block 706 in FIG. 7), and coupling the first electronic component 106(1) to the first power port 130(1) in the first circuit board 104(1) (block 708 in FIG. 7). A next step in the assembly process 700 can be providing the second electronic device 102(2) (block 710 in FIG. 7). Providing the second electronic device 102(2) can include providing a second circuit board 104(2) (block 712 in FIG. 7), coupling the second electronic component 106(2) (e.g., RFIC 128) to the second circuit board 104(2) (block 714 in FIG. 7). A next step in the assembly process 700 can be coupling the inductor 126 to the first circuit board 104(1) in the first direction (Z-axis direction) to couple the inductor 126 to the second power port 130(2) (block 716 in FIG. 7). A next step in the assembly process 700 can be coupling the inductor 126 to the second circuit board 104(2) to couple the inductor 126 to the second electronic component 106(2) (e.g., RFIC 128) (block 718 in FIG. 7).

Other assembly processes can be employed to assemble a circuit board device that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4.

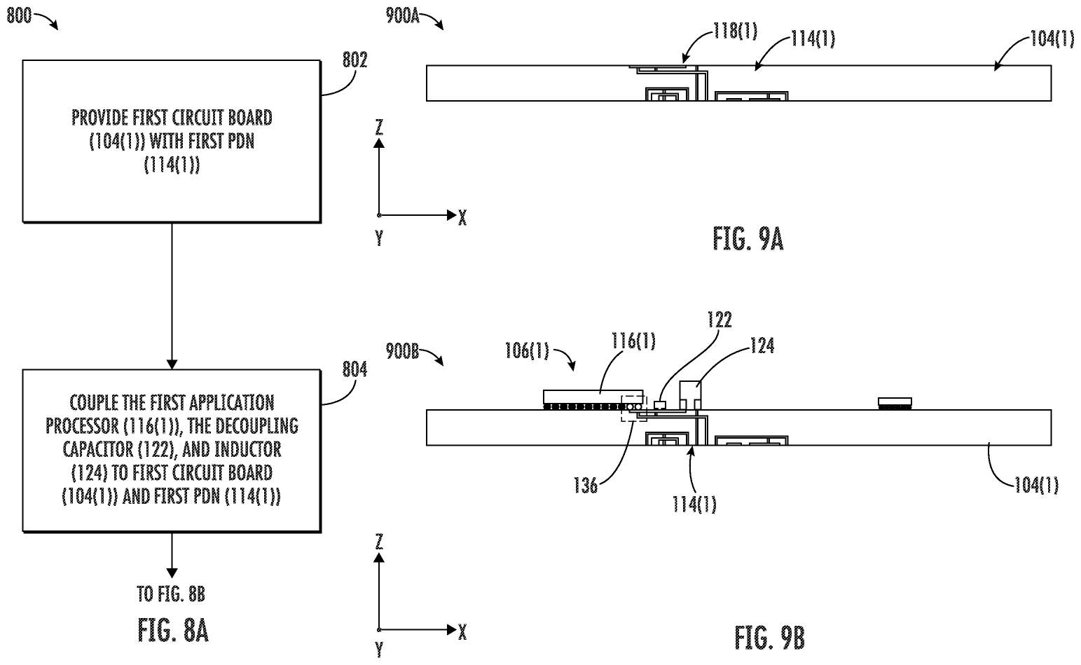

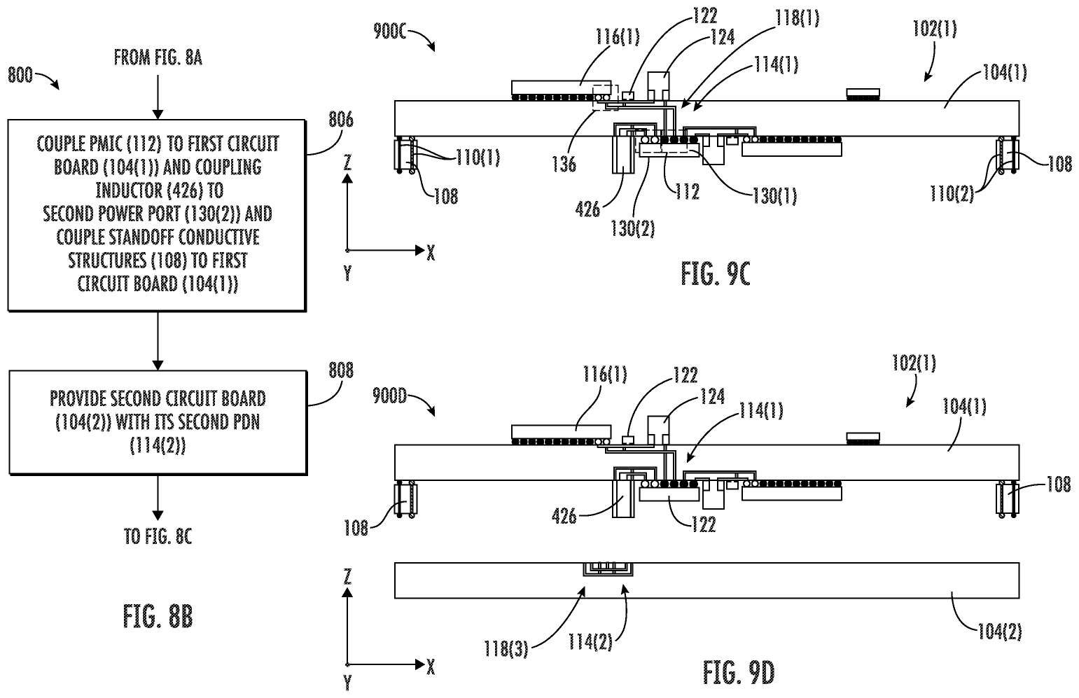

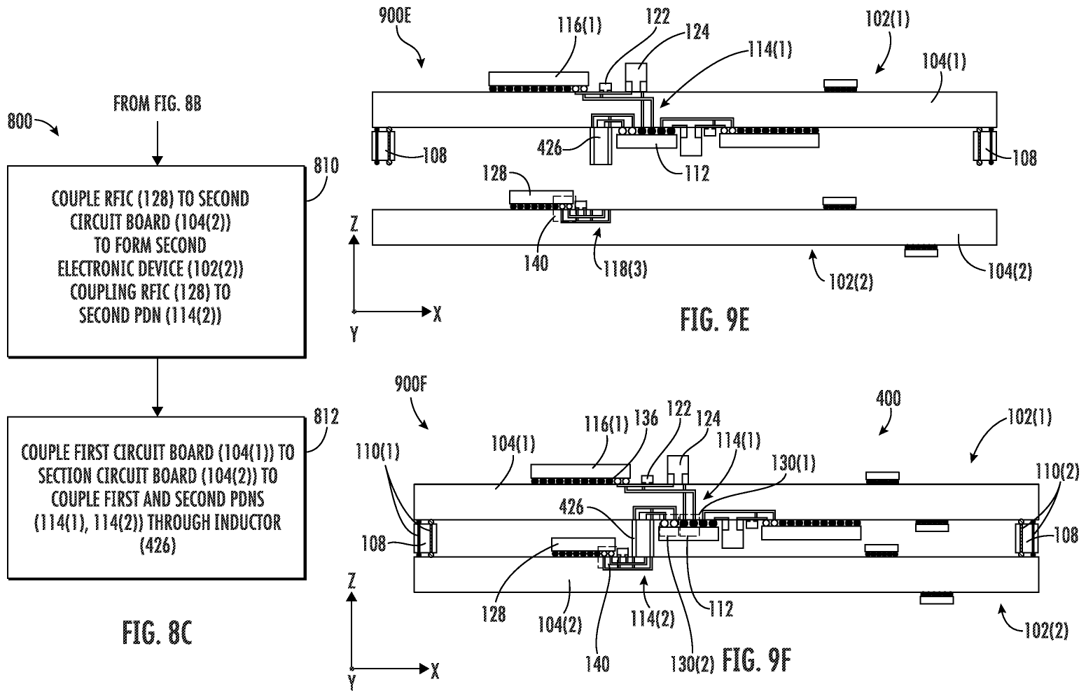

In this regard, FIGS. 8A-8C is a flowchart illustrating an exemplary assembly process 800 of assembling a circuit board device that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4. The assembly process 800 in FIGS. 8A-8C is discussed with regard to the circuit board device 400 in FIG. 4, but note that the assembly process 800 in FIGS. 8A-8C is not limited to fabricating the circuit board device 400 in FIG. 4. The assembly process 800 in FIGS. 8A-8D could be used to fabricate the circuit board device 100 in FIGS. 1A-1B as another example.

FIGS. 9A-9F are exemplary assembly stages 900A-900F during assembly of the circuit board device 400 according to the assembly process 800 in FIGS. 8A-8C. The assembly process 800 will be discussed in conjunction with the assembly stages 900A-900F in FIGS. 9A-9F.

In this regard, as shown in the exemplary assembly stage 900A in FIG. 9A. a first step in the assembly process 800 can be to provide the first circuit board 104(1) that includes the first metal interconnects 118(1) of the first PDN 114(1) (block 802 in FIG. 8A). Then, as shown in the exemplary assembly stage 900B in FIG. 9B, a next step in the assembly process 800 can be to couple the first electronic component 106(1) (the first application processor 116(1) in this example), the decoupling capacitor 122, and the inductor 124 to the first circuit board 104(1) (block 804 in FIG. 8A). The first input power port 136 of the application processor 116(1) is coupled to the first PDN 114(1).

Then, as shown in the exemplary assembly stage 900C in FIG. 9C, a next step in the assembly process 800 can be to couple the PMIC 112 to the first circuit board 104(1) (block 806 in FIG. 8B). Coupling the PMIC 112 to the first circuit board 104(1) couples the first and second power ports 130(1), 130(2) of the PMIC 112 to the first circuit board 104(1) and the first PDN 114(1). The assembly stage 900C also shows the inductor 426 being coupled to the first circuit board 104(1) and to the second power port 130(2) of the PMIC 112 (block 806 in FIG. 8B). The standoff conductive structures 108 are also coupled to the first circuit board 104(1) to prepare the first circuit board 104(1) to be stacked on the second circuit board 104(2) (block 806 in FIG. 8B).

Then, as shown in the exemplary assembly stage 900D in FIG. 9D, a next step in the assembly process 800 can be to provide the second circuit board 104(2) with the third metal interconnects 118(3) disposed therein to form the second PDN 114(2) (block 808 in FIG. 8B). The second circuit board 104(2) can be aligned with the first circuit board 104(1) and its standoff conductive structures 108 to prepare the first circuit board 104(1) to be coupled and stacked on the second circuit board 104(2) with the standoff conductive structures 108.

Then, as shown in the exemplary assembly stage 900E in FIG. 9E, a next step in the assembly process 800 can be to provide and couple the RFIC 128 to the second circuit board 104(1) to couple the RFIC 128 to the second PDN 114(2) in the second circuit board 104(2) (block 810 in FIG. 8C). The second input power port 140 of the RFIC 128 is coupled to the third metal interconnects 118(3) of the second PDN 114(2). Then, as shown in the exemplary assembly stage 900F in FIG. 9F, a next step in the assembly process 800 can be to couple the first circuit board 104(1) to the second circuit board 104(2) to couple the first PDN 114(1) in the first circuit board 104(1) to the second PDN 114(2) in the second circuit board 104(2) through the inductor 426 coupled to the first circuit board 104(1) and the second circuit board 104(2) (block 812 in FIG. 8C). This forms the circuit board device 400 like in FIG. 4. The first and second circuit boards 104(1), 104(2) are coupled together by the coupling of the standoff conductive structures 108 and the inductor 426 to the first and second circuit boards 104(1), 104(2).

Note as discussed herein, the term “couple” can mean directly connected or indirectly connected. When two objects are directly connected, there is no intervening component connected between the two objects. When two objects are indirectly connected, there may be an intervening component(s) connected between the two coupled objects.

A circuit board device that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4, and assembled according to, but not limited to, the exemplary assembly processes 700, 800 in FIGS. 7 and 8A-8C, may be provided or integrated in an electronic device, IC package, and/or any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

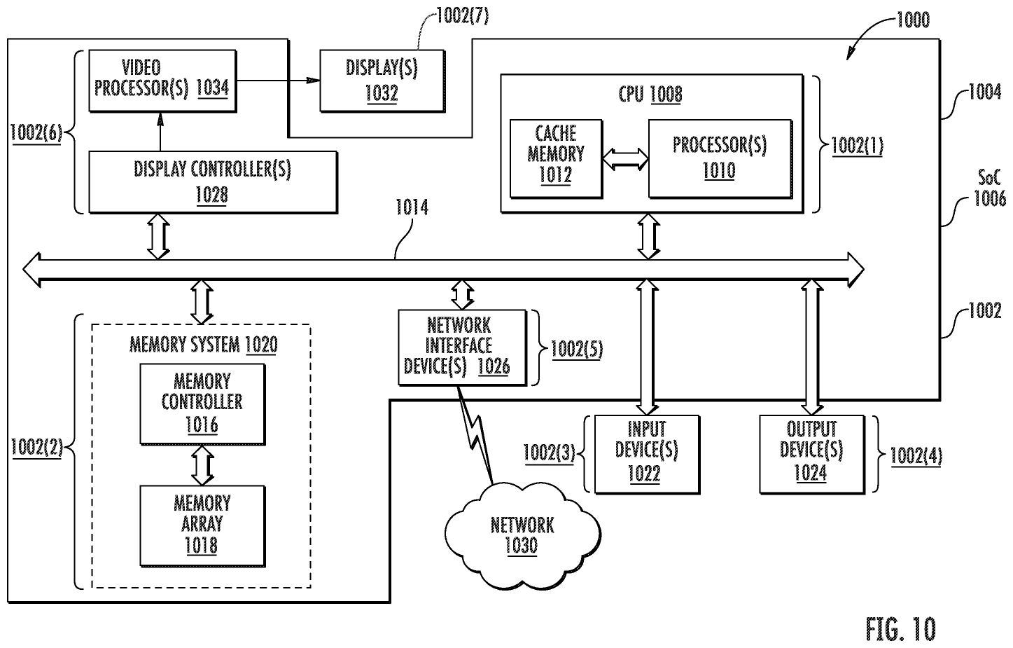

In this regard, FIG. 10 illustrates an example of a processor-based system 1000 that includes a circuit board device 1002, 1002(1)-1002(7) that includes a substrate that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4, and assembled according to, but not limited to, the exemplary assembly processes 700, 800 in FIGS. 7 and 8A-8C.

In this example, the processor-based system 1000 may be formed as circuit board device 1002 or an IC 1004 as a system-on-a-chip (SoC) 1006. The processor-based system 1000 includes a central processing unit (CPU) 1008 that includes one or more processors 1010, which may also be referred to as CPU cores or processor cores. The CPU 1008 may be provided in a circuit board device 1002(1). The CPU 1008 may have cache memory 1012 coupled to the CPU 1008 for rapid access to temporarily stored data. The CPU 1008 is coupled to a system bus 1014 and can intercouple master and slave devices included in the processor-based system 1000. As is well known, the CPU 1008 communicates with these other devices by exchanging address, control, and data information over the system bus 1014. For example, the CPU 1008 can communicate bus transaction requests to a memory controller 1016, as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples, that may be provided as or included in respective circuit board devices 1002(2)-1002(6). The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display controller(s) 1028 sends information to the display(s) 1032 to be displayed via one or more video processors 1034, which process the information to be displayed into a format suitable for the display(s) 1032. The display(s) 1032 can include any type of display, including, but not limited to, a cathode ray tube (CRT), a liquid crystal display (LCD), a plasma display, a light emitting diode (LED) display, etc. The display 1032 may be provided as or included in a circuit board device 1002(7).

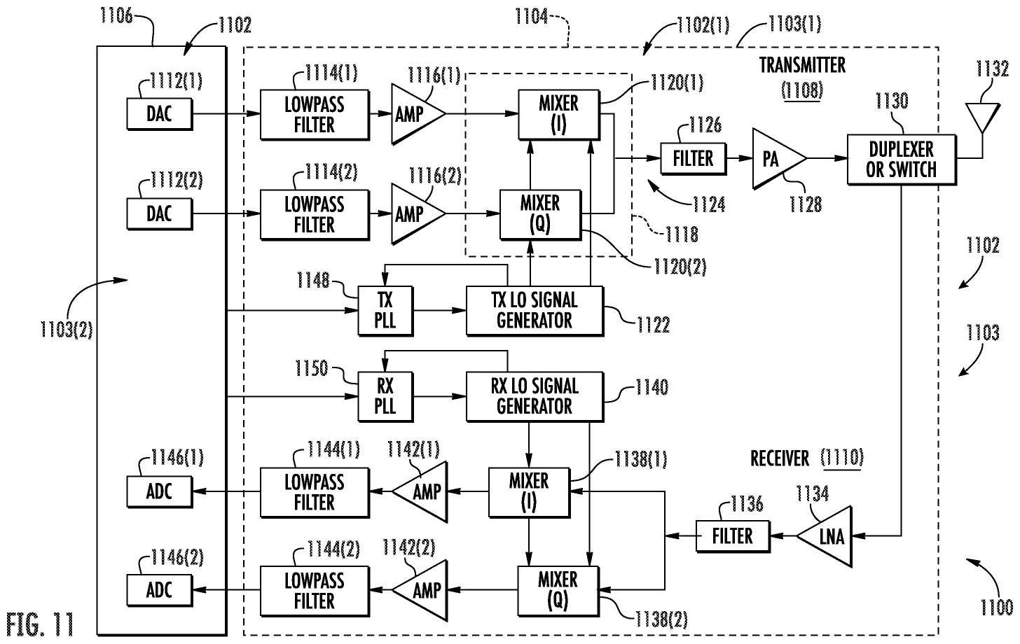

FIG. 11 illustrates an exemplary wireless communications device 1100 that includes radio frequency (RF) components that can be provided as or included in a circuit board device 1102 that includes a substrate that includes a first circuit board stacked on a second circuit board, and wherein the circuit board device further includes an inductor(s) coupled between the first circuit board and the second circuit board as part of a power routing path between the first circuit board and the second circuit board, for a PMIC on the first circuit board to be shared between the first and second circuit boards to manage the supply of power to the first circuit board and to a second electronic component(s) of the second circuit board, including, but not limited to, the circuit board devices 100, 400 in FIGS. 1A-1B and 4, and assembled according to, but not limited to, the exemplary assembly processes 700, 800 in FIGS. 7 and 8A-8C. The wireless communications device 1100 may be included or be provided in any of the above-referenced devices, as examples. The wireless communications device 1100 may be provided in an IC 1103. As shown in FIG. 11, the wireless communications device 1100 includes a transceiver 1104 and a data processor 1106. The transceiver 1104 and a data processor 1106 can be provided as or included in respective or the same circuit board devices 1102(1), 1102(2) and/or may be included in respective or the same ICs 1103(1), 1103(2). The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals, e.g., I and Q output currents, for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion. while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A circuit board device, comprising:
   a first electronic device, comprising:
      a first circuit board;
      a power management integrated circuit (IC) (PMIC) comprising a first power port coupled to the first circuit board and a second power port coupled to the first circuit board; and
      a first electronic component coupled to the first power port through the first circuit board; and
   a second electronic device, comprising:
      a second circuit board coupled to the first circuit board in a first direction; and
      a second electronic component coupled to the second circuit board; and
   an inductor coupled to the first circuit board and the second circuit board in the first direction;
      the inductor coupled to the second electronic component through the second circuit board; and
      the inductor coupled to the second power port through the first circuit board.
2. The circuit board device of clause 1, wherein:
   the PMIC is configured to distribute a first power signal through the first power port to the first electronic component; and
   the PMIC is further configured to distribute a second power signal through the second power port and the inductor to the second electronic component.
3. The circuit board device of clause 1 or 2, wherein:
   the second power port comprises a second power signal port and a second ground signal port;
   the inductor is coupled to the second power signal port through the first circuit board; and
   the second electronic component is coupled to the second signal port.
4. The circuit board device of any of clauses 1-3, wherein the inductor is coupled in series between the second power port and the second electronic component.
5. The circuit board device of any of clauses 1-4, wherein the inductor comprises:
   a first terminal connected to the first circuit board; and
   a second terminal connected to the first circuit board.
6. The circuit board device of clause 4 or 5, wherein:
   the first terminal is soldered to the first circuit board; and
   the second terminal is soldered to the first circuit board.
7. The circuit board device of any of clauses 1-6, wherein the inductor comprises an inductive core.
8. The circuit board device of any of clauses 1, 2 and 4-7, further comprising:
   a shorting conductor coupled to the first circuit board and the second circuit board in the first direction;
   wherein:
      the first circuit board comprises a second power metal interconnect and a second ground metal interconnect;
      the second power port comprises a second power signal port coupled to the second power metal interconnect and a second ground signal port coupled to the second ground metal interconnect;
      the second circuit board comprises a third power metal interconnect coupled to the second electronic component and a third ground metal interconnect coupled to the second electronic component;
      the inductor is coupled to the second power metal interconnect and the third power metal interconnect; and
      the shorting conductor is coupled to the second ground metal interconnect and the third ground metal interconnect.
9. The circuit board device of clause 8, wherein the shorting conductor is adjacent to the inductor.
10. The circuit board device of clause 8 or 9, wherein:
   the inductor comprises:
      a first terminal connected to the second power metal interconnect; and
      a second terminal connected to the third power metal interconnect; and the shorting conductor comprises:
      a third terminal connected to the second ground metal interconnect; and
      a fourth terminal connected to the third ground metal interconnect.
11. The circuit board device of any of clauses 1, 2 and 4-7, wherein:
   the inductor comprises a ground-shielded inductor comprising:
      an inductive core;
      a shorting conductor comprising a conductive core adjacent to the inductive core; and
      a dielectric material disposed between the inductive core and the conductive core;
   wherein:
      the first circuit board comprises a second power metal interconnect and a second ground metal interconnect;
      the second power port comprises a second power signal port coupled to the second power metal interconnect and a second ground signal port coupled to the second ground metal interconnect;
      the second circuit board comprises a third power metal interconnect coupled to the second electronic component and a third ground metal interconnect coupled to the second electronic component;
      the inductive core is coupled to the second power metal interconnect and the third power metal interconnect; and
      the conductive core is coupled to the second ground metal interconnect and the third ground metal interconnect.
12. The circuit board device of clause 11, wherein the dielectric material has a dielectric constant less than or equal to 4.0.
13. The circuit board device of clause 11 or 12, wherein:
   the inductive core comprises:
      a first terminal connected to the second power metal interconnect; and
      a second terminal connected to the third power metal interconnect; and the conductive core comprises:
      a third terminal connected to the second ground metal interconnect; and
      a fourth terminal connected to the third ground metal interconnect.
14. The circuit board device of clause 13, wherein:
   the first circuit board comprises a fourth ground metal interconnect;
   the second ground signal port is coupled to the fourth ground metal interconnect;
   the second circuit board comprises a fifth ground metal interconnect coupled to the second electronic component; and
   the conductive core further comprises:
      a fifth terminal disposed on a first side of the inductive core, the fifth terminal connected to the fourth ground metal interconnect; and
      a sixth terminal disposed on a second side of the inductive core opposite of the first side in a second direction orthogonal to the first direction, the sixth terminal connected to the fifth ground metal interconnect.
15. The circuit board device of clause 14, wherein the ground-shielded inductor comprises a box-shaped inductor, wherein:
   the conductive core comprises a conductive core comprising a box-shaped cavity comprising a plurality of inner surfaces; and
   the dielectric material is disposed on the plurality of inner surfaces;
   the inductive core comprises a box-shaped inductive core disposed within the box-shaped cavity and adjacent to the dielectric material.
16. The circuit board device of clause 14, wherein the ground-shielded inductor comprises a cylindrical-shaped inductor, wherein:
   the conductive core comprises a cylindrical-shaped conductive core comprising a cylindrical-shaped cavity comprising an inner surface;
   the dielectric material is disposed on the inner surface; and
   the inductive core comprises a cylindrical-shaped inductive core disposed within the cylindrical-shaped cavity and adjacent to the dielectric material.
17. The circuit board device of any of clauses 1-16, wherein:
   the first circuit board comprises:
      a first power metal interconnect; and
      a second power metal interconnect;
   the first power port comprises a first power signal port coupled to the first power metal interconnect;
   the second power port comprises a second power signal port coupled to the second power metal interconnect;
   the second circuit board comprises:
      a third power metal interconnect coupled to the second electronic component; and
   the inductor is coupled to the second power metal interconnect and the third power metal interconnect.
18. The circuit board device of any of clauses 1-17, wherein:
   the first circuit board comprises a first surface and a second surface opposite the first surface in the first direction, the second surface adjacent to the second circuit board; and
   the PMIC is coupled to the second surface of the first circuit board.
19. The circuit board device of any of clauses 1-18, further comprising one or more standoff conductive structures each coupled to the first circuit board and the second circuit board in the first direction;
   each standoff conductive structure of the one or more standoff conductive structures comprising:
      at least one vertical conductor coupled to the first circuit board and the second circuit board;
      the at least one vertical conductor coupled to the first electronic component and the second electronic component.
20. The circuit board device of any of clauses 1-19, wherein the one or more standoff conductive structures comprise an interposer frame.
21. The circuit board device of any of clauses 1-20, wherein:
   the first electronic component comprises a processor; and
   the second electronic component comprises a radio-frequency (RF) IC (RFIC).
22. The circuit board device of any of clauses 1-21, wherein the PMIC comprises a switched mode power supply (SMPS).
23. The circuit board device of any of clauses 1-22 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
24. A method of assembling a circuit board device, comprising:
   providing a first electronic device, comprising:
      providing a first circuit board;
      coupling a first power port and a second power port of a power management integrated circuit (PMIC) to the first circuit board; and
      coupling a first electronic component to the first power port; and
   providing a second electronic device, comprising:
      providing a second circuit board; and
      coupling a second electronic component to the second circuit board;
      coupling an inductor to the first circuit board in a first direction to couple the inductor to the second power port; and
      coupling the inductor to the second circuit board to couple the inductor to the second electronic component.
25. The method of clause 24, comprising coupling the inductor in series between the second power port and the second electronic component.
26. The method of clause 24 or 25, wherein:
   coupling the inductor to the first circuit board comprises coupling the inductor to a second power metal interconnect in a second power signal port of the second power port in the first circuit board;
   coupling the inductor to the second circuit board comprises coupling the inductor to a third power metal interconnect in the second circuit board coupled to the second electronic component; and
   further comprising:
      coupling a shorting conductor to a second ground metal interconnect in a second ground signal port of the second power port in the first circuit board in the first direction; and
      coupling the shorting conductor to a third ground metal interconnect in the second circuit board coupled to the second electronic component.
27. The method of clause 24 or 25, wherein:
   the inductor comprises a ground-shielded inductor comprising:
      an inductive core;
      a shorting conductor comprising a conductive core adjacent to the inductive core; and
      a dielectric material disposed between the inductive core and the conductive core;
   wherein:
      coupling the inductor to the first circuit board comprises coupling the conductive core to a second power metal interconnect in a second power signal port of the second power port in the first circuit board;
      coupling the inductor to the second circuit board comprises coupling the conductive core to a third power metal interconnect in the second circuit board coupled to the second electronic component; and
      further comprising:
         coupling the shorting conductor to a second ground metal interconnect in a second ground signal port of the second power port in the first circuit board in the first direction; and
         coupling the shorting conductor to a third ground metal interconnect in the second circuit board coupled to the second electronic component.
28. The method of any of clauses 24-27, further comprising coupling one or more standoff conductive structures to the first circuit board and the second circuit board in the first direction.

What is claimed is:

1. A circuit board device, comprising:
a first electronic device, comprising:
a first circuit board;
a power management integrated circuit (IC) (PMIC) comprising a first power port coupled to the first circuit board and a second power port coupled to the first circuit board; and
a first electronic component coupled to the first power port through the first circuit board; and
a second electronic device, comprising:
a second circuit board coupled to the first circuit board in a first direction; and
a second electronic component coupled to the second circuit board; and
an inductor coupled to the first circuit board and the second circuit board in the first direction;
the inductor coupled to the second electronic component through the second circuit board; and
the inductor coupled to the second power port through the first circuit board.

2. The circuit board device of claim 1, wherein:
the PMIC is configured to distribute a first power signal through the first power port to the first electronic component; and
the PMIC is further configured to distribute a second power signal through the second power port and the inductor to the second electronic component.

3. The circuit board device of claim 1, wherein:
the second power port comprises a second power signal port and a second ground signal port;
the inductor is coupled to the second power signal port through the first circuit board; and
the second electronic component is coupled to the second signal port.

4. The circuit board device of claim 1, wherein the inductor is coupled in series between the second power port and the second electronic component.

5. The circuit board device of claim 1, wherein the inductor comprises:
a first terminal connected to the first circuit board; and
a second terminal connected to the first circuit board.

6. The circuit board device of claim 4, wherein:
the first terminal is soldered to the first circuit board; and
the second terminal is soldered to the first circuit board.

7. The circuit board device of claim 1, wherein the inductor comprises an inductive core.

8. The circuit board device of claim 1, further comprising:
a shorting conductor coupled to the first circuit board and the second circuit board in the first direction;
wherein:
the first circuit board comprises a second power metal interconnect and a second ground metal interconnect;
the second power port comprises a second power signal port coupled to the second power metal interconnect and a second ground signal port coupled to the second ground metal interconnect;
the second circuit board comprises a third power metal interconnect coupled to the second electronic component and a third ground metal interconnect coupled to the second electronic component;
the inductor is coupled to the second power metal interconnect and the third power metal interconnect; and
the shorting conductor is coupled to the second ground metal interconnect and the third ground metal interconnect.

9. The circuit board device of claim 8, wherein the shorting conductor is adjacent to the inductor.

10. The circuit board device of claim 8, wherein:
the inductor comprises:
a first terminal connected to the second power metal interconnect; and
a second terminal connected to the third power metal interconnect; and
the shorting conductor comprises:
a third terminal connected to the second ground metal interconnect; and
a fourth terminal connected to the third ground metal interconnect.

11. The circuit board device of claim 1, wherein:
the inductor comprises a ground-shielded inductor comprising:
an inductive core;
a shorting conductor comprising a conductive core adjacent to the inductive core; and
a dielectric material disposed between the inductive core and the conductive core;
wherein:
the first circuit board comprises a second power metal interconnect and a second ground metal interconnect;
the second power port comprises a second power signal port coupled to the second power metal interconnect and a second ground signal port coupled to the second ground metal interconnect;
the second circuit board comprises a third power metal interconnect coupled to the second electronic component and a third ground metal interconnect coupled to the second electronic component;
the inductive core is coupled to the second power metal interconnect and the third power metal interconnect; and
the conductive core is coupled to the second ground metal interconnect and the third ground metal interconnect.

12. The circuit board device of claim 11, wherein the dielectric material has a dielectric constant less than or equal to 4.0.

13. The circuit board device of claim 11, wherein:
the inductive core comprises:
a first terminal connected to the second power metal interconnect; and
a second terminal connected to the third power metal interconnect; and
the conductive core comprises:
a third terminal connected to the second ground metal interconnect; and
a fourth terminal connected to the third ground metal interconnect.

14. The circuit board device of claim 13, wherein:
the first circuit board comprises a fourth ground metal interconnect;
the second ground signal port is coupled to the fourth ground metal interconnect;
the second circuit board comprises a fifth ground metal interconnect coupled to the second electronic component; and
the conductive core further comprises:
a fifth terminal disposed on a first side of the inductive core, the fifth terminal connected to the fourth ground metal interconnect; and
a sixth terminal disposed on a second side of the inductive core opposite of the first side in a second direction orthogonal to the first direction, the sixth terminal connected to the fifth ground metal interconnect.

15. The circuit board device of claim 14, wherein the ground-shielded inductor comprises a box-shaped inductor, wherein:
the conductive core comprises a conductive core comprising a box-shaped cavity comprising a plurality of inner surfaces; and
the dielectric material is disposed on the plurality of inner surfaces;
the inductive core comprises a box-shaped inductive core disposed within the box-shaped cavity and adjacent to the dielectric material.

16. The circuit board device of claim 14, wherein the ground-shielded inductor comprises a cylindrical-shaped inductor, wherein:
the conductive core comprises a cylindrical-shaped conductive core comprising a cylindrical-shaped cavity comprising an inner surface;
the dielectric material is disposed on the inner surface; and
the inductive core comprises a cylindrical-shaped inductive core disposed within the cylindrical-shaped cavity and adjacent to the dielectric material.

17. The circuit board device of claim 1, wherein:
the first circuit board comprises:
a first power metal interconnect; and
a second power metal interconnect;
the first power port comprises a first power signal port coupled to the first power metal interconnect;
the second power port comprises a second power signal port coupled to the second power metal interconnect;
the second circuit board comprises:
a third power metal interconnect coupled to the second electronic component; and
the inductor is coupled to the second power metal interconnect and the third power metal interconnect.

18. The circuit board device of claim 1, wherein:
the first circuit board comprises a first surface and a second surface opposite the first surface in the first direction, the second surface adjacent to the second circuit board; and
the PMIC is coupled to the second surface of the first circuit board.

19. The circuit board device of claim 1, further comprising one or more standoff conductive structures each coupled to the first circuit board and the second circuit board in the first direction;
each standoff conductive structure of the one or more standoff conductive structures comprising:
at least one vertical conductor coupled to the first circuit board and the second circuit board;
the at least one vertical conductor coupled to the first electronic component and the second electronic component.

20. The circuit board device of claim 19, wherein the one or more standoff conductive structures comprise an interposer frame.

21. The circuit board device of claim 1, wherein:
the first electronic component comprises a processor; and
the second electronic component comprises a radio-frequency (RF) IC (RFIC).

22. The circuit board device of claim 1, wherein the PMIC comprises a switched mode power supply (SMPS).

23. The circuit board device of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

24. A method of assembling a circuit board device, comprising:
providing a first electronic device, comprising:
providing a first circuit board;
coupling a first power port and a second power port of a power management integrated circuit (PMIC) to the first circuit board; and
coupling a first electronic component to the first power port; and
providing a second electronic device, comprising:
providing a second circuit board; and
coupling a second electronic component to the second circuit board;
coupling an inductor to the first circuit board in a first direction to couple the inductor to the second power port; and
coupling the inductor to the second circuit board to couple the inductor to the second electronic component.

25. The method of claim 24, comprising coupling the inductor in series between the second power port and the second electronic component.

26. The method of claim 24, wherein:
coupling the inductor to the first circuit board comprises coupling the inductor to a second power metal interconnect in a second power signal port of the second power port in the first circuit board;
coupling the inductor to the second circuit board comprises coupling the inductor to a third power metal interconnect in the second circuit board coupled to the second electronic component; and
further comprising:
coupling a shorting conductor to a second ground metal interconnect in a second ground signal port of the second power port in the first circuit board in the first direction; and
coupling the shorting conductor to a third ground metal interconnect in the second circuit board coupled to the second electronic component.

27. The method of claim 24, wherein:
the inductor comprises a ground-shielded inductor comprising:
an inductive core;
a shorting conductor comprising a conductive core adjacent to the inductive core; and
a dielectric material disposed between the inductive core and the conductive core;
wherein:
coupling the inductor to the first circuit board comprises coupling the conductive core to a second power metal interconnect in a second power signal port of the second power port in the first circuit board;
coupling the inductor to the second circuit board comprises coupling the conductive core to a third power metal interconnect in the second circuit board coupled to the second electronic component; and
further comprising:
coupling the shorting conductor to a second ground metal interconnect in a second ground signal port of the second power port in the first circuit board in the first direction; and
coupling the shorting conductor to a third ground metal interconnect in the second circuit board coupled to the second electronic component.

28. The method of claim 24, further comprising coupling one or more standoff conductive structures to the first circuit board and the second circuit board in the first direction.
